(19) United States
(12) Patent Application Publication
(10) Pub. No.: US 2007/0170523 A1
(43) Pub. Date: Jul. 26, 2007

(54) CIRCUIT SUBSTRATE AND PACKAGING THEREOF AND THE METHOD FOR FABRICATING THE PACKAGING

(75) Inventors: Yao-Sheng Lin, Hsinchu Hsien (TW); Tai-Hong Chen, Hsinchu Hsien (TW)

Correspondence Address: ISHIMARU & ZAHRT LLP, 333 W. EL CAMINO REAL, SUITE 330, SUNNYVALE, CA, 94087, US

(73) Assignee: INDUSTRIAL TECHNOLOGY RESEARCH INSTITUTE, Hsinchu Hsien (TW)

(21) Appl. No.: 11/468,341

(22) Filed: Aug. 30, 2006

(30) Foreign Application Priority Data
Jan. 26, 2006 (TW) 095103012

(51) Int. Cl. H01L 29/76

(52) U.S. Cl. 257/401

(57) ABSTRACT

A circuit substrate and its packaging and the method for fabricating the packaging are provided. A plurality of electrodes are formed on the surface of the circuit substrate, the electrodes are formed with fork structures, so that when the circuit substrate expands/contracts due to thermal processes, such that the probability of alignment with electrodes of an external circuit board is increased. Meanwhile, overlapping portions of the fork structures with the electrodes of the circuit board can be cut away to avoid short circuit. Thus, electrode misalignment due to electrode pitch variation of the traditional circuit substrate as a result of thermal deformation can be effectively eliminated.

### FIELD OF THE INVENTION

The present invention relates to a circuit substrate and packaging thereof and the method for fabricating the packaging, and more particularly, to a flexible substrate and its packaging applicable to a display and the method for fabricating the flexible substrate packaging.

### BACKGROUND OF THE INVENTION

Flat Panel Displays (FPDs) have become one of the most important electronic applications due to the progress of technology. The FPDs have been applied to various fields, such as TVs, outdoor panels, display screens of electronic instruments and electronic watches etc. The optoelectronic industry has made great effort in research and development, the FPDs has evolved from the early Cathode Ray Tubes (CRTs) to the now popular Liquid Crystal Displays (LCDs). Furthermore, a type of FPDs called Organic Light Emitting Diodes (OLEDs) have promising future due to advantages such as self-illuminating, high contrast, high luminance, low driving voltage and compactness etc.

In addition, although Thin-Film Transistor-LCDs (TFT-LCDs) driven by thin-film transistors based on glass substrates are currently a popular choice for many, “soft” substrates such as plastic and flexible substrates which compared to glass substrates are lighter and less fragile have become the focus of the next generation applications.

Currently, flexible substrates mainly use plastic substrates made of Polyethersulfone (PES), which has a glass transition temperature of about 200˜220° C., and thermal expansion coefficient of about 50˜60 ppm/° C. However, since flexible substrates tend to change with temperature, expansion of the plastic substrates may occur due to high temperature cycles in the display manufacturing processes, such that the pitch between electrodes thereon may become too large to allow effective alignment of the electrodes of the flexible substrates with electrodes of a flexible circuit board for electrical connections, creating problems such as electrical failure or short circuit.

Referring to FIG. 1 (PRIOR ART), the problem of the pitch between neighboring electrodes 100 on a traditional flexible substrate 10 becoming too large or too small due to temperature variation is illustrated. As a result, the flexible substrate 10 is thermally deformed, such that there is no sufficient area to interface electrodes 110 on a flexible circuit board 11 with the electrodes 100 of the flexible substrate 10 causing electrical failure or more than one electrodes 110 on the flexible circuit board 11 overlap the same electrode on flexible substrate 10 causing electrical short circuit.

Many have tried to find a solution to the problem of thermal stress or deformation due to different thermal expansions of various materials. For example, U.S. Pat. No. 5,644,373 discloses a LCD device that has a pair of substrate mutually separated from each other by a predetermined distance, so that a liquid crystal can be disposed between the substrates, wherein the substrate is a different material with thermal expansion difference within positive or negative 50% to avoid the problem of misalignment. However, this method uses a glass substrate and does not address the problem of thermal stress and expansion of flexible substrates.

Moreover, U.S. Pat. No. 6,489,573 discloses an electrode bonding structure that reduces the effect of thermal expansion in bonding process of the flexible circuit board. The electrode bonding structure comprises a substrate, a circuit board and an Anisotropic Conductive Film (ACF). A dielectric layer and indenting pads are formed on the surface of the substrate. The inner surface of the indenting pads is lower than the surface of the dielectric layer of the substrate by a depth H3. The circuit board is parallel to the substrate with a circuit dielectric layer and bump pads formed thereon. The bump pads are higher than surface of the circuit dielectric layer by about H1. The ACF with a thickness of H2 is disposed between the substrate and the circuit board. In bonding, the bump pads are correspondingly coupled to the indenting pads, and H1>(H2+H3), thereby reducing the effect of thermal expansion in bonding the circuit board.

Nonetheless, the above technique is only applied to the bonding between a glass substrate and a flexible circuit board; it does not address the thermal expansion in bonding a flexible substrate and a flexible circuit board.

Another approach commonly used in this field is to estimate the pitch of the electrodes after thermal deformation and make flexible circuit board with corresponding electrode pitch accordingly. However, such a method has a complicated manufacturing process and higher production cost.

Moreover, during bonding of flexible substrates and circuit boards, if the manufacturing machine is not properly controlled or faulty, misalignment may occur between the substrates and the circuit boards. As a result, the whole batch may have to be discarded, increasing the production cost.

Therefore, there is a need for a flexible substrate and its packaging and the method for fabricating the packaging that enhance reliability in the alignment process and effectively solves the problem of thermal deformation of the flexible substrates as described above.

### SUMMARY OF THE INVENTION

In the light of forgoing drawbacks, a primary objective of the present invention is to provide a circuit substrate and its packaging and the method for fabricating the packaging to enhance alignment of the circuit substrate after thermal deformation.

Another objective of the present invention is to provide a circuit substrate and its packaging and the method for fabricating the packaging that reduces the effect of expansion or contraction of plastic material of the circuit substrate after thermal processes on the subsequent electrical alignment.

Still another objective of the present invention is to provide a circuit substrate and its packaging and the method for fabricating the packaging that eliminates the need of making a circuit board with customized electrode pitch for bonding with a conventional circuit substrate after thermal deformation, thus avoiding complicated fabricating process and high production cost.

Yet another objective of the present invention is to provide a circuit substrate and its packaging and the method for fabricating the packaging that avoids discarding a whole batch of substrates having misaligned electrodes with circuit boards due to fault or poorly operated fabricating machinery.

In accordance with the above and other objectives, the present invention provides a circuit substrate. A plurality of electrodes are formed on the surface of the circuit substrate characterized by fork structures, so that when the circuit substrate expands/contracts due to thermal processes, such that the probability of alignment with electrodes of an external circuit board is increased. Meanwhile, overlapping portions of the fork structures with the electrodes of the circuit board can be cut away to avoid short circuit.

The present invention also discloses a circuit substrate packaging, comprising a circuit substrate with a plurality of electrodes formed thereon, wherein the electrodes are formed with fork structures; and a circuit board with a plurality of electrodes formed thereon, the electrodes of the circuit board being correspondingly bonded and electrically connected to the fork structures of the circuit substrate.

The present invention further discloses a method for fabricating a circuit substrate packaging, comprising: providing a circuit substrate and a circuit board, a surface of the circuit substrate and the circuit board is respectively formed with a plurality of electrodes, the electrodes formed on the surface of the circuit substrate being formed with fork structures; correspondingly bonding the electrodes of the circuit board with the fork structures of the circuit substrate; and cutting away an overlapping portion of the fork structures corresponding to the same electrode on the circuit substrate that being bonded to different electrodes of the circuit board.

Thus, by virtue of the circuit substrate and its packaging and the method for fabricating the packaging according to the present invention, in which electrodes for external electrical connections are formed with fork structures to increase the alignment probability with the electrodes of the external circuit board, thus avoiding the problem of misalignment of electrodes of the circuit board and the traditional circuit substrate due to thermal deformation of the electrode pitch.

Furthermore, when the circuit substrate and the circuit board in the present invention are bonded together, only the overlapping portion of fork structures belonging to the same electrode on the circuit substrate that are bonded to different electrodes of the circuit board need to be cut off, thereby avoiding electrical short circuit. Thus, there is no need to provide a customized flexible circuit board with suitable electrode pitch made to correspond to the electrodes of the circuit substrate after deformation. Therefore, the fabricating process is simplified and production cost is reduced.

### BRIEF DESCRIPTION OF THE DRAWINGS

The present invention can be more fully understood by reading the following detailed description of the preferred embodiments, with reference made to the accompanying drawings, wherein:

FIG. 1 (PRIOR ART) is a plane schematic diagram illustrating the problem of electrode misalignment between a conventional flexible substrate and a circuit board in which the pitch between neighboring electrodes on the traditional flexible substrate becoming too large or too small due to temperature variation;

FIG. 2A is a plane schematic diagram of a first embodiment of the circuit substrate of the present invention;

FIG. 2B is a plane schematic diagram of a first embodiment of the circuit substrate packaging of the present invention;

FIGS. 3A to 3C are cross sectional schematic diagrams for illustrating the fabricating process of the circuit substrate packaging of the present invention;

FIG. 4A is a plane schematic diagram of a second embodiment of the circuit substrate of the present invention; and

FIG. 4B is a plane schematic diagram of a second embodiment of the circuit substrate packaging of the present invention.

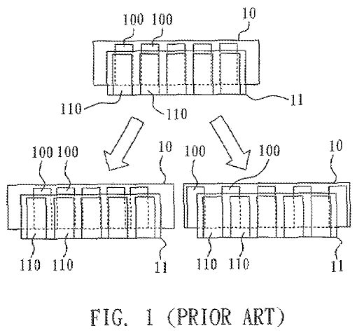

### DETAILED DESCRIPTION OF THE EMBODIMENTS

The present invention is described by the following specific embodiments. Those with ordinary skills in the arts can readily understand the other advantages and functions of the present invention after reading the disclosure of this specification. The present invention can also be implemented with different embodiments. Various details described in this specification can be modified based on different viewpoints and applications without departing from the scope of the present invention.

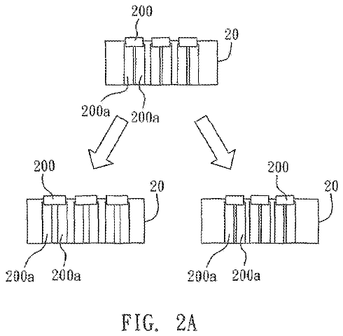

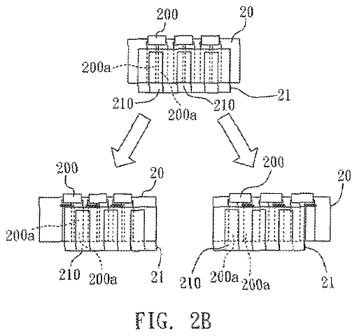

Referring to FIG. 2A, a plane schematic diagram of a circuit substrate 20 of the present invention is shown. A plurality of electrodes 200 are formed on the circuit substrate 20. The electrodes 200 are characterized in that fork structures 200a are formed. The electrodes 200 used for external electrically connections extend outward and are split into two such that the alignment probability of the electrodes with electrodes of an external circuit board is improved.

The circuit substrate 20 is an insulating plastic substrate, such as a flexible substrate applicable to a flexible display. The insulating plastic material used for the circuit substrate 20 may for example be Polyethersulfone (PES), which has a glass transition temperature of about 200˜220° C., and a thermal expansion coefficient of about 50˜60 ppm/° C. It should be noted that the circuit substrate 20 of the present invention is not limited to a flexible substrate, but can be applied to any kind of circuit substrate having electrode pitch varied with the thermal environment.

The fork structures 200a formed in the electrodes 200 for electrical signal propagation on the circuit substrate 20 allows better alignment with electrodes of an external circuit board, even if the circuit substrate 20 expands/contract due to thermal processes. Good electrical bonding with the external circuit board can be provided by the fork structures 200a.

Referring to FIG. 2B, a packaging of a circuit substrate of the present invention is also shown. The packaging comprises a circuit substrate 20 with a plurality of electrodes 200 thereon, wherein the electrodes 200 are formed with fork structures 200a; and a circuit board 21 with a plurality of electrodes 210 thereon. The electrodes 210 of the circuit board 21 are correspondingly bonded to the electrode fork structures 200a of the circuit board 20.

In the packaging, even if the circuit substrate 20 is under high temperature thermal processes, such that the material substantially expands/contracts and causing the electrode pitch to vary, the electrodes 210 of the circuit board 21 can still be easily aligned to the electrodes 200 of the circuit substrate 20 via the inventive fork structures 200a. Moreover, in the case of the fork structure 200a of the same electrode of the circuit substrate 20 being bonded to different electrodes 210 of the circuit board 21, only the part that is overlapped need to be cut off, thus avoiding electrical short circuit. Additionally, the circuit board 21 is for example a flexible circuit board (FPC).

It should be noted that the fork structures formed in the electrodes of the circuit substrate extend outward and split into two in this embodiment, but the electrode can also be formed with fork structures without extending outward. In such a way, electrical bonding can still be provided, overlapping portion of the fork structure of the same electrode of the circuit substrate bonded to different electrodes of the circuit board can be cut off to avoid electrical short circuit. Thus, good electrical bonding with the circuit board can be provided effectively by using the fork structures.

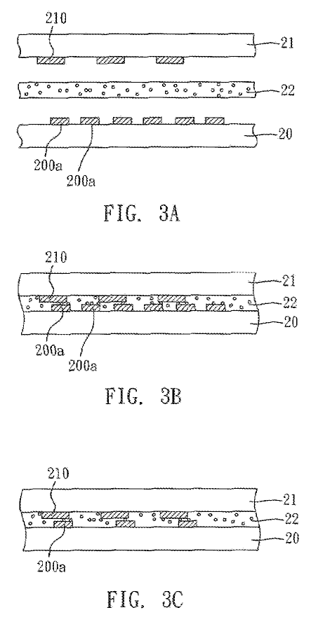

Referring to FIGS. 3A to 3C, cross sectional schematic diagrams for illustrating the fabricating process of the circuit substrate packaging of the present invention are shown. As shown in FIG. 3A, a circuit substrate 20 and a circuit board 21 are first provided. A plurality of electrodes 200 and 210 are respectively formed on the surface of the circuit substrate 20 and the circuit board 21. The electrodes 200 of the circuit substrate 20 are formed with fork structures 200a thereon.

As shown in FIG. 3B, a high molecular gel is disposed between the circuit substrate 20 and the circuit board 21, such as an Anisotropic Conductive Film (ACF) 22, thermal pressing of the circuit substrate 20 and the circuit board 21 is performed, so that the electrodes 210 of the circuit board 21 correspondingly bond and electrically conduct the electrode fork structures 200a of the circuit substrate 20.

As shown in FIG. 3C, the overlapping portion of the fork structures corresponding to the same electrode 200 on the circuit substrate 200 bonded to different electrodes 210 of the circuit board 21 are cut away. This cutting can be performed by a laser or a punching tool to avoid any electrical short circuit.

Additionally, as described with the conventional processes, in the case that the fabricating machinery is faulty or wrongly operated, causing misalignment of the electrodes of the circuit board and the circuit substrate, such that the electrodes are overlapped and short circuited, the overlapping portion of the fork structures can be cut off to avoid the whole batch being discarded and increase of production cost.

Thus, by virtue of the circuit substrate and its packaging and the method for fabricating the packaging according to the present invention, in which electrodes for external electrical connections are formed with fork structures to increase the alignment probability with the electrodes of the external circuit board, thus avoiding the problem of misalignment of electrodes of the circuit board and the traditional circuit substrate due to thermal deformation of the electrode pitch.

Furthermore, when the circuit substrate and the circuit board in the present invention are bonded together, only the overlapping portion of fork structures belonging to the same electrode on the circuit substrate that are bonded to different electrodes of the circuit board need to be cut off, thereby avoiding electrical short circuit. Thus, there is no need to provide a customized flexible circuit board with suitable electrode pitch made to correspond to the electrodes of the circuit substrate after deformation. Therefore, the fabricating process is simplified and production cost is reduced.

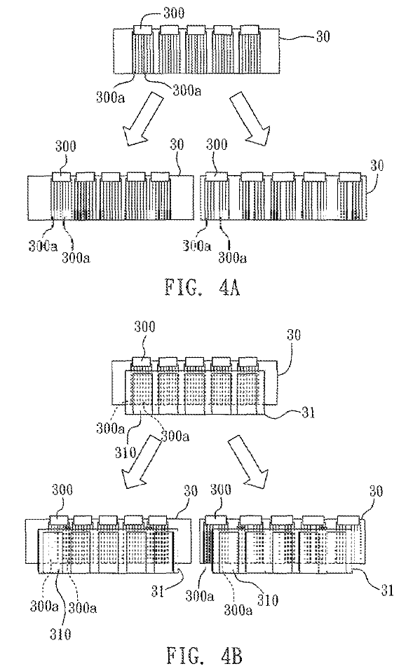

Referring to FIGS. 4A and 4B, a plane schematic diagram depicting a second embodiment of the circuit substrate and a second embodiment of the circuit substrate packaging of the present invention is shown.

As shown, the circuit substrate and its packaging of the second embodiment are similar to those of the above embodiment. The main difference is in that the fork structures 300a of the electrodes 300 on the circuit substrate 30 are in rail-like shapes. In this way, not only the alignment probability of the electrodes 300 of the circuit substrate 30 with electrodes 310 of an external circuit board 31 can be increased, but the number of conductive particles in the anisotropic conductive film captured underneath the circuit substrate 30 and the circuit board 31, thereby reducing bonding resistance and increasing conductivity.

Moreover, in the second embodiment of the present invention, when rail-like fork structures on the circuit substrate 30 corresponding to the same electrode are bonded to different electrodes of the circuit board 31, cutting of the overlapping portion can be more easily carried out.

The above embodiments are only used to illustrate the principles of the present invention, and they should not be construed as to limit the present invention in any way. The above embodiments can be modified by those with ordinary skills in the arts without departing from the scope of the present invention as defined in the following appended claims.

What is claimed is:

1. A circuit substrate formed with a plurality of electrodes thereon, which is characterized in that the electrodes are formed with fork structures.

2. The circuit substrate of claim 1, wherein the circuit substrate is a flexible substrate applied to a display device.

3. The circuit substrate of claim 1, wherein the fork structures form the electrodes on a surface of the circuit substrate for external signal connection to increase alignment probability of the electrodes of the circuit substrate with electrodes of an external circuit board.

4. The circuit substrate of claim 3, wherein the circuit board is a Flexible Printed Circuit (FPC) board.

5. The circuit substrate of claim 3, wherein the circuit substrate is electrically connected with and the circuit board via an Anisotropic Conductive Film (ACF).

6. The circuit substrate of claim 3, wherein an overlapping portion of the fork structures of the same electrode of the circuit substrate bonded to different electrodes of the circuit board is cut off to avoid electrical short circuit.

7. The circuit substrate of claim 6, wherein the cutting is performed by a laser or a punching tool.

8. The circuit substrate of claim 1, wherein the circuit substrate adopts Polyethersulfone (PES) as an insulating material.

9. The circuit substrate of claim 1, wherein the fork structures of the electrodes formed on the circuit substrate have a rail shape.

10. The circuit substrate of claim 1, wherein the fork structures of the electrodes can be selected from one of extending outward and not extending outward.

11. A circuit substrate packaging, comprising:
a circuit substrate with a plurality of electrodes formed thereon, wherein the electrodes are formed with fork structures; and
a circuit board with a plurality of electrodes formed thereon, the electrodes of the circuit board being correspondingly bonded and electrically connected to the fork structures of the circuit substrate.

12. The circuit substrate packaging of claim 11, wherein the circuit substrate is a flexible substrate applied to a display device.

13. The circuit substrate packaging of claim 11, wherein the fork structures form the electrodes on a surface of the circuit substrate for external signal connection to increase alignment probability of the electrodes of the circuit substrate with electrodes of an external circuit board.

14. The circuit substrate packaging of claim 11, wherein the circuit board is an FPC board.

15. The circuit substrate packaging of claim 11, wherein the circuit substrate is electrically connected with the circuit board via an ACF.

16. The circuit substrate packaging of claim 11, wherein an overlapping portion of the fork structures of the same electrode of the circuit substrate bonded to different electrodes of the circuit board is cut off to avoid electrical short circuit.

17. The circuit substrate packaging of claim 17, wherein the cutting is performed by a laser or a punching tool.

18. The circuit substrate packaging of claim 11, wherein the circuit substrate adopts PES as an insulating material.

19. The circuit substrate packaging of claim 11, wherein the fork structures of the electrodes formed on the circuit substrate have a rail shape.

20. The circuit substrate packaging of claim 11, wherein the fork structures of the electrodes can be selected from one of extending outward and not extending outward.

21. A method for fabricating a circuit substrate packaging, comprising:
providing a circuit substrate and a circuit board, surfaces of the circuit substrate and the circuit board are respectively formed with a plurality of electrodes, the electrodes formed on the surface of the circuit substrate being formed with fork structures;
correspondingly bonding the electrodes of the circuit board with the fork structures of the circuit substrate; and
cutting away an overlapping portion of the fork structures corresponding to the same electrode on the circuit substrate that being bonded to different electrodes of the circuit board.

22. The method of claim 21, wherein the circuit substrate is a flexible substrate applied to a display device.

23. The method of claim 21, wherein the circuit board is an FPC board.

24. The method of claim 21, wherein the circuit substrate is electrically connected with the circuit board via an ACF.

25. The method of claim 21, wherein the cutting is performed by a laser or a punching tool.

26. The method of claim 21, wherein the circuit substrate adopts PES as an insulating material.

27. The method of claim 21, wherein the fork structures of the electrodes formed on the circuit substrate have a rail shape.

28. The method of claim 21, wherein the fork structures of the electrodes can be selected from one of extending outward and not extending outward.
